(19) United States
(12) Patent Application Publication
(10) Pub. No.: US 2026/0323830 A1
(43) Pub. Date: Oct. 15, 2026

(54) SEMICONDUCTOR DEVICE

(71) Applicant: FUJI ELECTRIC CO., LTD., Kawasaki-shi (JP)

(72) Inventors: Koji OSAKI, Matsumoto-city (JP); Akira HIRAO, Matsumoto-city (JP); Taisuke FUKUDA, Matsumoto-city (JP)

(73) Assignee: FUJI ELECTRIC CO., LTD., Kawasaki-shi (JP)

(21) Appl. No.: 19/688,240

(22) Filed: May 26, 2026

Related U.S. Application Data
(63) Continuation of application No. PCT/JP2025/016780, filed on May 7, 2025.

(30) Foreign Application Priority Data
Jun. 7, 2024 (JP) 2024-093197

(51) Int. Cl. H05K 1/14; H05K 1/02; H05K 1/181; H10W 40/20; H10W 90/00; H10W 90/10

(52) U.S. Cl. CPC H05K 1/145; H05K 1/0209; H05K 1/0256; H05K 1/181; H10W 40/235; H10W 90/10; H05K 2201/042; H05K 2201/10166; H05K 2201/10318; H05K 2201/10522; H10W 90/721; H10W 90/731

(57) ABSTRACT

A semiconductor device includes an insulating circuit board and a printed circuit board. A first semiconductor chip and a second semiconductor chip are respectively disposed on a first conductive plate and a second conductive plate of the insulating circuit board. The printed circuit board includes a first conductive layer conductively connected to an electrode of the first semiconductor chip and the second conductive plate, a second conductive layer conductively connected to an electrode of the second semiconductor chip and a third conductive plate, and an insulating layer between the first and second conductive layers. The third conductive plate extends from the center toward the outer edge of the insulating circuit board and is connected to an external terminal. The third conductive plate and the second conductive layer are connected by a conductive member. A cooler is provided on a lower surface of an insulating member of the insulating circuit board.

### CROSS-REFERENCE TO RELATED APPLICATION(S)

This application is a continuation application of International Application PCT/JP2025/016780 filed on May 7, 2025, which designated the U.S., and claims priority to Japanese Patent Application No. 2024-093197, filed on Jun. 7, 2024, the entire contents of which are incorporated herein by reference.

### BACKGROUND OF THE INVENTION

### 1. Field of the Invention

The embodiment discussed herein relates to a semiconductor device.

### 2. Background of the Related Art

In a semiconductor device, a bus bar is provided as a heat dissipation member at a part connecting a first semiconductor switch element and a second semiconductor switch element (see Japanese Laid-open Patent Publication No. 2017-139380). Another configuration includes an insulating circuit board to which a conductor pattern member, on which a semiconductor chip is mounted, is stuck and a printed circuit board that faces the insulating circuit board, and has a conductive connecting member of the printed circuit board connected to the semiconductor chip and the conductor pattern member (see International Publication Pamphlet No. WO 2014/103133).

### SUMMARY OF THE INVENTION

According to an aspect of the present disclosure, there is provided a semiconductor device, including: an insulating circuit board including a first conductive plate, a second conductive plate, and a third conductive plate disposed on an insulating member, the third conductive plate extending from a center of the insulating circuit board toward an outer edge of the insulating circuit board; a first semiconductor chip disposed on the first conductive plate; a first external terminal connected to the first conductive plate; a second semiconductor chip disposed on the second conductive plate, each of the first and second semiconductor chips having an electrode on an upper surface thereof; a second external terminal connected to the second conductive plate; a third external terminal connected to the third conductive plate; a printed circuit board, including: a first conductive layer, which is conductively connected to the electrode of the first semiconductor chip and the second conductive plate, a second conductive layer, which is conductively connected to the electrode of the second semiconductor chip and the third conductive plate, the second conductive layer being disposed facing the third conductive plate, and an insulating layer which is disposed between the first conductive layer and the second conductive layer, the printed circuit board being disposed facing the insulating circuit board with the first semiconductor chip and the second semiconductor chip in between; and a conductive member that connects the third conductive plate and the second conductive layer, wherein the insulating member is configured to have a cooler provided on a lower surface thereof.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF THE DRAWINGS

FIG. 1 is a plan view depicting an example of a chip layout of a semiconductor device;

FIG. 2 is a diagram illustrating an example of a cross section of the semiconductor device;

FIG. 3 is a diagram illustrating an example of a circuit configuration of a semiconductor chip;

FIG. 4 is a diagram illustrating an example of a pattern configuration of the lowermost conductive layer;

FIG. 5 is a diagram illustrating an example of a pattern configuration of an inner conductive layer;

FIG. 6 is a diagram illustrating an example of a pattern configuration of an inner conductive layer;

FIG. 7 is a diagram depicting an example of a pattern configuration of the uppermost wiring portion;

FIG. 8 is a diagram depicting an example of an overview of a semiconductor device;

FIG. 9 is a diagram illustrating a first configuration example of the conductive member;

FIG. 10 is a diagram illustrating a second configuration example of the conductive member;

FIG. 11 is a diagram illustrating a third configuration example of the conductive member;

FIG. 12 is a diagram illustrating an example of the shape of the conductive plate;

FIG. 13 is a diagram illustrating an example of a cross section of a semiconductor device of a first comparative example;

FIG. 14 is a diagram illustrating an example of a cross section of a semiconductor device of a second comparative example; and

FIG. 15 is a diagram illustrating an analysis result of Joule heat of the printed circuit board.

### DETAILED DESCRIPTION OF THE INVENTION

Several embodiments are described below with reference to the drawings. Note that in the following description, the expression “upper surface” refers to a surface that faces upward from the plane of the drawings. In the same way, the expressions “upward” and “upper part” refer to a direction extending upwardly out from the plane of the drawings. The expression “lower surface” refers to a surface facing downward from the plane of the drawings. In the same way, “downward” refers to a direction extending downward from the plane of the drawings. These directions have the same meaning for all of the drawings. The expressions “upper surface”, “upward”, “upper part”, “lower surface”, and “lower part” are merely convenient expressions for specifying relative positional relationships, and do not limit the technical idea of the present disclosure. The expression “connection” in the present specification refers to an “electrical connection” unless otherwise specified.

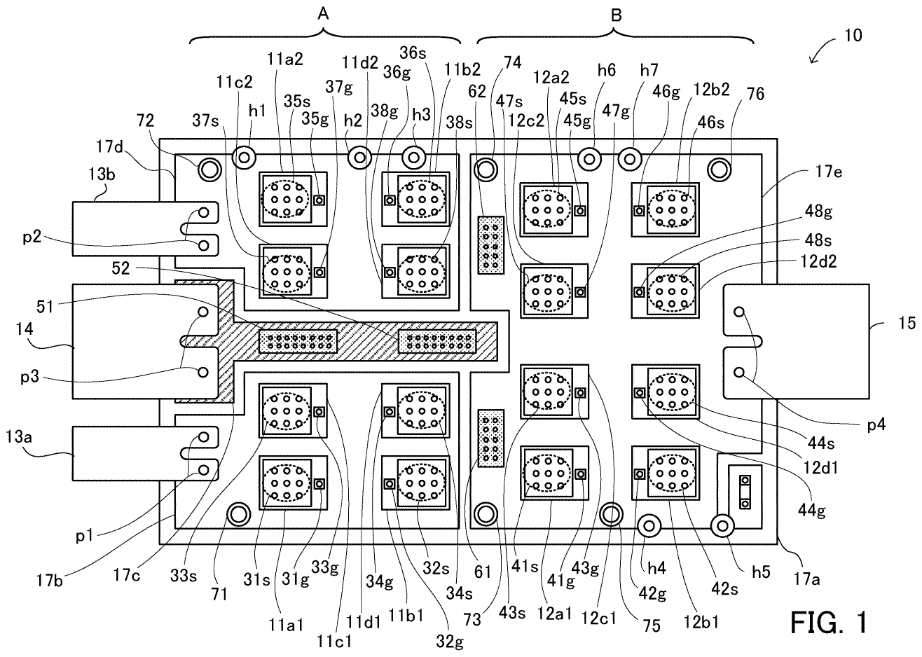

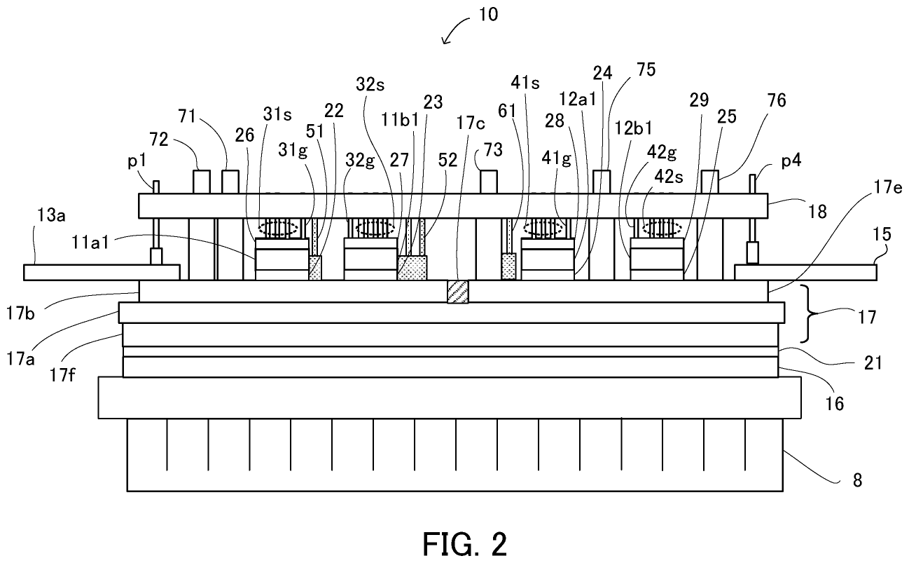

FIG. 1 is a plan view depicting an example chip layout of a semiconductor device. FIG. 2 is a diagram depicting an example cross section of the semiconductor device. Note that an insulating encapsulating member and a printed circuit board are not depicted in FIG. 1. The insulating encapsulating member is also omitted from FIG. 2.

The semiconductor device 10 is configured as a half-bridge circuit module including an upper arm portion A and a lower arm portion B. The upper arm portion A of the semiconductor device 10 includes semiconductor chips 11a1, 11b1, 11c1, 11d1, 11a2, 11b2, 11c2, and 11d2 (which may be collectively referred to as the “semiconductor chips 11”). The lower arm portion B of the semiconductor device 10 includes semiconductor chips 12a1, 12b1, 12c1, 12d1, 12a2, 12b2, 12c2, and 12d2 (which may be collectively referred to as the “semiconductor chips 12”).

The semiconductor chips 11 (first semiconductor chips) and the semiconductor chips 12 (second semiconductor chips) may have silicon carbide as a main component. As one example, these semiconductor chips may be power metal-oxide-semiconductor field-effect transistors (MOSFET). Each of the semiconductor chips 11 and 12 in this case includes a drain electrode as an input electrode on the lower surface, and a gate electrode as a control electrode and a source electrode as an output electrode on the upper surface.

The semiconductor chips 11 and 12 may alternatively have silicon as a main component. Such semiconductor chips may include reverse-conducting insulated gate bipolar transistor (RC-IGBT) that have both the functions of an IGBT and a freewheeling diode (FWD). Such semiconductor chips include a collector electrode as an input electrode on a lower surface, and a gate electrode as a control electrode and an emitter electrode as an output electrode on an upper surface. Note that in the present embodiment, a case where the semiconductor chips 11 and 12 are power MOSFETs will be described as one example.

The semiconductor device 10 includes a heat dissipation plate (heat dissipation copper base) 16, an insulating circuit board 17 provided on the heat dissipation plate 16, and a printed circuit board 18 with a multilayer structure that is disposed above the insulating circuit board 17 so as to face the insulating circuit board 17 (the multilayer structure of the printed circuit board 18 will be described later). The heat dissipation plate 16 is a plate-shaped member that is substantially rectangular in plan view. Corner portions of the heat dissipation plate 16 may be chamfered into rounded or beveled shapes.

The heat dissipation plate 16 is made of a metal with superior heat dissipation properties. Example metals include copper, aluminum, and an alloy containing at least one of these metals. The surface of the heat dissipation plate 16 may be plated to improve corrosion resistance. Examples of the plating material used here include nickel, nickel-phosphorus alloy, and nickel-boron alloy.

The insulating circuit board 17 is connected to the front surface of the heat dissipation plate 16 via a bonding material 21, and the cooler 8 is fixed to the rear surface of the heat dissipation plate 16. As examples, the cooler 8 is a heat sink including one or more fins or a cooling device that uses water cooling.

The insulating circuit board 17 includes an insulating member 17a, conductive plates 17b, 17c, 17d, and 17e formed on the front surface of the insulating member 17a, and a metal plate 17f formed on the rear surface of the insulating member 17a. The conductive plates 17b and 17d (first conductive plates) are formed in the upper arm portion A, and the conductive plate 17e (second conductive plate) is formed in the lower arm portion B. The conductive plate 17c (third conductive plate) is configured to extend from the center of the insulating circuit board 17 toward the outer edge, and is formed on the insulating member 17a in the center of the region of the upper arm A.

The insulating member 17a is rectangular in shape in plan view. Corner portions of the insulating member 17a may be chamfered into rounded or beveled shapes. The insulating member 17a is made of ceramics or resin material that has high thermal conductivity. Example ceramics include aluminum oxide, silicon nitride, or a material containing aluminum nitride as a main component. As an example of the resin material, epoxy resin to which a filler that is electrically insulating and has higher thermal conductivity than the resin material is added may be used.

The conductive plates 17b, 17c, 17d, and 17e are made of a metal with superior electrical conductivity. Example metals include copper, aluminum, or an alloy containing at least one of these metals. To improve the corrosion resistance of the conductive plates 17b, 17c, 17d, and 17e, a plating treatment may be performed. Examples of the plating material used here include nickel, nickel-phosphorus alloy, and nickel-boron alloy.

The metal plate 17f is made of a metal with superior thermal conductivity as a main component. Example metals include copper, aluminum, or an alloy containing at least one of these metals. To improve the corrosion resistance of the metal plate, a plating treatment may be performed. Examples of the plating material used here include nickel, nickel-phosphorus alloy, and nickel-boron alloy.

The semiconductor chips 11a1, 11b1, 11c1, and 11d1 and the external terminal 13a (first external terminal) are mounted on the conductive plate 17b, and the semiconductor chips 11a2, 11b2, 11c2, and 11d2 and the external terminal 13b (first external terminal) are mounted on the conductive plate 17d. The semiconductor chips 12a1, 12b1, 12c1, 12d1, 12a2, 12b2, 12c2, and 12d2 and an external terminal 15 (second external terminal) are mounted on the conductive plate 17e. An external terminal 14 (third external terminal) is mounted on the conductive plate 17c.

Note that FIG. 2 depicts a state where the semiconductor chip 11a1 is connected to the conductive plate 17b via the bonding material 22 and the semiconductor chip 11b1 is connected to the conductive plate 17b via the bonding material 23. The semiconductor chip 12a1 is connected to the conductive plate 17e via the bonding material 24, and the semiconductor chip 12b1 is connected to the conductive plate 17e via the bonding material 25.

On the other hand, the external terminal 13a is connected to the conductive plate 17b by a bonding material, and the external terminal 13b is connected to the conductive plate 17d by a bonding material. The external terminal 14 is connected to the conductive plate 17c by a bonding material, and the external terminal 15 is connected to the conductive plate 17e by a bonding material. Solder or sintered material may be used as the bonding material. Note that the external terminals 13a, 13b, 14, and 15 may be connected to the conductive plates of the insulating circuit board 17 by laser welding or ultrasonic welding.

The external terminals 13a and 13b are P terminals that serve as positive electrode-side terminals in the half-bridge circuit, and the external terminal 14 is an N terminal that serves as a negative electrode-side terminal in the half-bridge circuit. The external terminal 15 is an output terminal of the half-bridge circuit. Bosses p1, p2, p3, and p4, which protrude toward the insulating circuit board 17, are formed at parts the external terminals 13a, 13b, 14, and 15 that are contacted by the bonding material. The bosses p1, p2, p3, and p4 may be formed by press machining when the external terminals 13a, 13b, 14, and 15 are formed. The height of these bosses ensures that the bonding material is sufficiently thick.

One end of each post electrode 31s, 32s, 33s, and 34s, which consist of a plurality of electrodes, is connected by a bonding material to the source electrodes of the semiconductor chips 11a1, 11b1, 11c1, and 11d1. The other ends of the post electrodes 31s, 32s, 33s, and 34s are connected to the printed circuit board 18. One end of each post electrode 31g, 32g, 33g, and 34g is connected by a bonding material to the gate electrode of the semiconductor chips 11a1, 11b1, 11c1, and 11d1. The other ends of the post electrodes 31g, 32g, 33g, and 34g are connected to the printed circuit board 18.

One end of each post electrode 35s, 36s, 37s, and 38s, which consist of a plurality of electrodes, is connected by a bonding material to the source electrodes of the semiconductor chips 11a2, 11b2, 11c2, and 11d2. The other ends of the post electrodes 35s, 36s, 37s, and 38s are connected to the printed circuit board 18. One end of each post electrode 35g, 36g, 37g, and 38g is connected by a bonding material to the gate electrodes of the semiconductor chips 11a2, 11b2, 11c2, and 11d2. The other ends of the post electrodes 35g, 36g, 37g, and 38g are connected to the printed circuit board 18.

One end of each post electrode 41s, 42s, 43s, and 44s, which consist of a plurality of electrodes, is connected by a bonding material to the source electrodes of the semiconductor chips 12a1, 12b1, 12c1, and 12d1. The other ends of the post electrodes 41s, 42s, 43s, and 44s are connected to the printed circuit board 18. One end of each post electrode 41g, 42g, 43g, and 44g is connected by a bonding material to the gate electrodes of the semiconductor chips 12a1, 12b1, 12c1, and 12d1. The other ends of the post electrodes 41g, 42g, 43g, and 44g are connected to the printed circuit board 18.

One end of each post electrode 45s, 46s, 47s, and 48s, which consist of a plurality of electrodes, is connected by a bonding material to the source electrodes of the semiconductor chips 12a2, 12b2, 12c2, and 12d2. The other ends of the post electrodes 45s, 46s, 47s, and 48s are connected to the printed circuit board 18. One end of each post electrode 45g, 46g, 47g, and 48g is connected by a bonding material to the gate electrodes of the semiconductor chips 12a2, 12b2, 12c2, and 12d2. The other ends of the post electrodes 45g, 46g, 47g, and 48g are connected to the printed circuit board 18.

Note that in FIG. 2, one end of the post electrode 31s is connected to the source electrode of the semiconductor chip 11a1 via a bonding material 26, and the other end of the post electrode 31s is connected to the printed circuit board 18. One end of the post electrode 31g is connected to the gate electrode of the semiconductor chip 11a1 via the bonding material 26, and the other end of the post electrode 31g is connected to the printed circuit board 18.

One end of the post electrode 32s is connected to the source electrode of the semiconductor chip 11b1 via a bonding material 27, and the other end of the post electrode 32s is connected to the printed circuit board 18. One end of the post electrode 32g is connected to the gate electrode of the semiconductor chip 11b1 via the bonding material 27, and the other end of the post electrode 32g is connected to the printed circuit board 18.

One end of the post electrode 41s is connected to the source electrode of the semiconductor chip 12a1 via a bonding material 28, and the other end of the post electrode 41s is connected to the printed circuit board 18. One end of the post electrode 41g is connected to the gate electrode of the semiconductor chip 12a1 via the bonding material 28, and the other end of the post electrode 41g is connected to the printed circuit board 18.

One end of the post electrode 42s is connected to the source electrode of the semiconductor chip 12b1 via a bonding material 29, and the other end of the post electrode 42s is connected to the printed circuit board 18. One end of the post electrode 42g is connected to the gate electrode of the semiconductor chip 12b1 via the bonding material 29, and the other end of the post electrode 42g is connected to the printed circuit board 18.

As one example, solder is used for the bonding materials 21, 22, 23, 24, 25, 26, 27, 28, and 29. Lead-free solder is used as this solder. As examples, this lead-free solder contains at least one of tin-silver-copper alloy, tin-antimony alloy, tin-zinc-bismuth alloy, tin-copper alloy, and tin-silver-indium-bismuth alloy as a main component. Instead of solder, sintered metal may be used. The material of the sintered metal is silver, gold, nickel, copper, or an alloy containing at least one of these metals.

On the other hand, one end of each conductive member 51 and 52 is connected to the conductive plate 17c, and the other ends of the conductive members 51 and 52 are connected to the printed circuit board 18. One end of each intermediate conductive member 61 and 62 located in an intermediate part between the upper arm portion A and the lower arm portion B is connected to the conductive plate 17e, and the other end of each intermediate conductive members 61 and 62 is connected to the printed circuit board 18.

The conductive plate 17b is provided with a conductive pin terminal 71 and the conductive plate 17d is provided with a conductive pin terminal 72. The conductive plate 17e is provided with conductive pin terminals 73, 74, 75, and 76. FIG. 2 depicts a state where one end of the conductive pin terminal 71 is connected to the conductive plate 17b and the other end of the conductive pin terminal 71 passes through and protrudes from the printed circuit board 18. A conductive pin terminal 72 connected to the conductive plate 17d passes through and protrudes from the printed circuit board 18. FIG. 2 also depicts a state where one end of each of the conductive pin terminals 73, 75, and 76 is connected to the conductive plate 17e and the other end of each of the conductive pin terminals 73, 75, and 76 passes through and protrudes from the printed circuit board 18.

In the semiconductor device 10, the insulating circuit board 17 and the printed circuit board 18 are connected to each other as described above via the post electrodes, the conductive pin terminals, the conductive members, and the intermediate conductive members to produce a three-dimensional wiring structure above the semiconductor chips. With this configuration, the printed circuit board 18 is supported above the insulating circuit board 17, and the semiconductor chips 11 and 12 are electrically connected to each other via a conductive layer (described later) formed on the printed circuit board 18.

The semiconductor device 10 is provided with holes h1, h2, h3, h4, h5, h6, and h7 for fixing the insulating circuit board 17 and the printed circuit board 18 with attachment pins. The holes h1, h2, and h3 are formed in the conductive plate 17d. The holes h4, h5, h6, and h7 are formed in the conductive plate 17e.

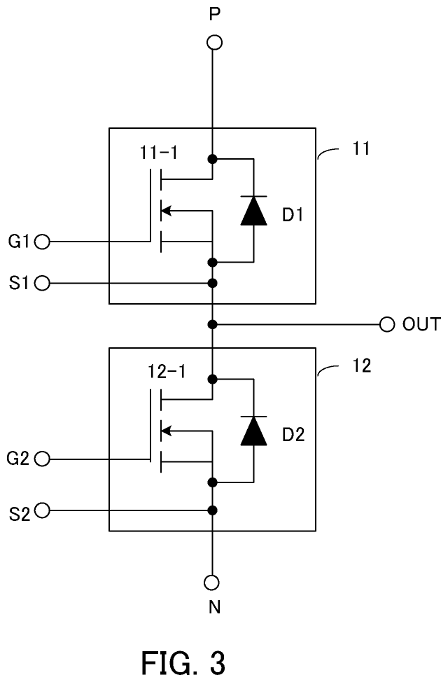

FIG. 3 depicts an example circuit configuration of semiconductor chips. An example configuration of a semiconductor chip 11 in the upper arm portion A and a semiconductor chip 12 in the lower arm portion B is depicted. The switching element of the semiconductor chip 11 is constituted by a MOSFET 11-1 and a parasitic diode D1 of the MOSFET 11-1. The switching element of the semiconductor chip 12 is constituted by a MOSFET 12-1 and a parasitic diode D2 of the MOSFET 12-1.

The drain electrode of the MOSFET 11-1 is connected to a P terminal and the cathode of the parasitic diode D1. The gate electrode of the MOSFET 11-1 is connected to a gate terminal G1. The source electrode of the MOSFET 11-1 is connected to the anode of the parasitic diode D1, an auxiliary source terminal S1, an output terminal OUT, the drain electrode of the MOSFET 12-1, and the cathode of the parasitic diode D2. The gate electrode of the MOSFET 12-1 is connected to a gate terminal G2. The source electrode of the MOSFET 12-1 is connected to the anode of the parasitic diode D2, the auxiliary source terminal S2, and the N terminal.

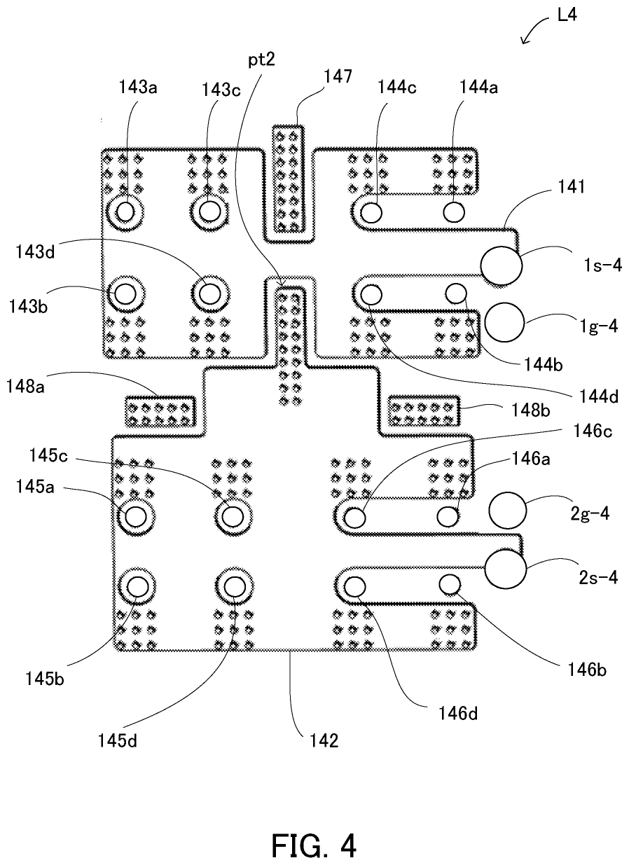

Next, the multilayer structure of the printed circuit board 18 will be described with reference to FIGS. 4 to 7. The printed circuit board 18 disposed above the insulating circuit board 17 includes a plurality of conductive layers including a lowermost conductive layer, an inner conductive layer, and an uppermost wiring portion. The printed circuit board 18 has a multilayer structure in which these conductive layers are disposed in an insulating layer and are stacked with insulating layers interposed therebetween.

FIG. 4 depicts an example pattern configuration of the lowermost conductive layer. The lowermost conductive layer L4 is disposed on the lowermost layer of the printed circuit board 18. On the upper arm side of the lowermost conductive layer L4, a conductive layer 141 is connected to the post electrodes 31s, 32s, 33s, and 34s connected to the source electrodes of the semiconductor chips 11a1, 11b1, 11c1, and 11d1, respectively. The conductive layer 141 is also connected to the post electrodes 35s, 36s, 37s, and 38s connected to the source electrodes of the semiconductor chips 11a2, 11b2, 11c2, and 11d2, respectively. Note that the lowermost conductive layer L4 is provided with an upper-arm-side auxiliary source terminal connection portion 1s-4, which is connected to the conductive layer 141.

Conductive layers 143a, 143b, 143c, and 143d are connected to the post electrodes 31g, 32g, 33g, and 34g connected to the gate electrodes of the semiconductor chips 11a1, 11b1, 11c1, and 11d1, respectively. Conductive layers 144a, 144b, 144c, and 144d are connected to the post electrodes 35g, 36g, 37g, and 38g connected to the gate electrodes of the semiconductor chips 11a2, 11b2, 11c2, and 11d2, respectively. Note that the lowermost conductive layer L4 is provided with an upper-arm-side gate terminal connection portion 1g-4.

On the lower arm side of the lowermost conductive layer L4, a conductive layer 142 is connected to the post electrodes 41s, 42s, 43s, and 44s connected to the source electrodes of the semiconductor chips 12a1, 12b1, 12c1, and 12d1, respectively. The conductive layer 142 is also connected to the post electrodes 45s, 46s, 47s, and 48s connected to the source electrodes of the semiconductor chips 12a2, 12b2, 12c2, and 12d2, respectively. Note that the lowermost conductive layer L4 is provided with a lower-arm-side auxiliary source terminal connection portion 2s-4, which is connected to the conductive layer 142.

Conductive layers 145a, 145b, 145c, and 145d are connected to the post electrodes 41g, 42g, 43g, and 44g connected to the gate electrodes of the semiconductor chips 12a1, 12b1, 12c1, and 12d1, respectively. Conductive layers 146a, 146b, 146c, and 146d are connected to the post electrodes 45g, 46g, 47g, and 48g connected to the gate electrodes of the semiconductor chips 12a2, 12b2, 12c2, and 12d2, respectively. Note that the lowermost conductive layer L4 is provided with a lower-arm-side gate terminal connection portion 2g-4.

On the other hand, the conductive layer 147 is connected to the conductive member 51. The conductive member 52 is connected to the conductive layer 142 at a position pt2. A conductive layer 148a is connected to the intermediate conductive member 61, and a conductive layer 148b is connected to the intermediate conductive member 62.

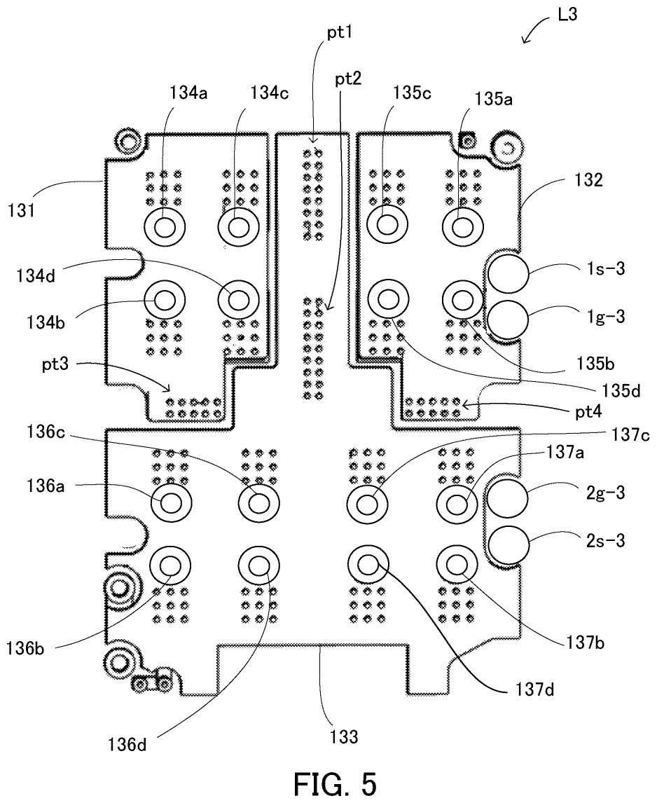

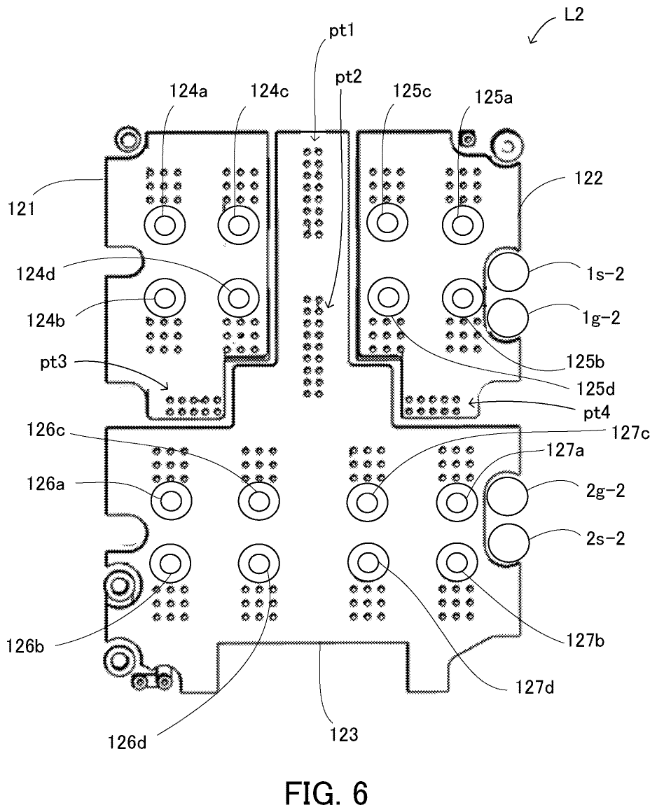

FIGS. 5 and 6 depict example pattern configurations of the inner conductive layer. An inner conductive layer L3 depicted in FIG. 5 is positioned between the lowermost conductive layer L4 and an inner conductive layer L2 depicted in FIG. 6. On the upper arm side of the inner conductive layer L3, a conductive layer 131 (first conductive layer) is connected to the post electrodes 31s, 32s, 33s, and 34s connected to the source electrodes of the semiconductor chips 11a1, 11b1, 11c1, and 11d1, respectively. Conductive layers 134a, 134b, 134c, and 134d are connected to the post electrodes 31g, 32g, 33g, and 34g connected to the gate electrodes of the semiconductor chips 11a1, 11b1, 11c1, and 11d1, respectively. In addition, the intermediate conductive member 61 is connected to the conductive layer 131 at a position pt3.

A conductive layer 132 (first conductive layer) is connected to the post electrodes 35s, 36s, 37s, and 38s connected to the source electrodes of the semiconductor chips 11a2, 11b2, 11c2, and 11d2, respectively. Conductive layers 135a, 135b, 135c, and 135d are connected to the post electrodes 35g, 36g, 37g, and 38g connected to the gate electrodes of the semiconductor chips 11a2, 11b2, 11c2, and 11d2, respectively. In addition, the intermediate conductive member 62 is connected to the conductive layer 132 at a position pt4.

The inner conductive layer L3 is provided with an upper-arm-side auxiliary source terminal connection portion 1s-3, which is connected to the auxiliary source terminal connection portion 1s-4 depicted in FIG. 4. The inner conductive layer L3 is also provided with the upper-arm-side gate terminal connection portion 1g-3, which is connected to the gate terminal connection portion 1g-4 depicted in FIG. 4.

On the lower arm side of the inner conductive layer L3, a conductive layer 133 (second conductive layer) is connected to the post electrodes 41s, 42s, 43s, and 44s connected to the source electrodes of the semiconductor chips 12a1, 12b1, 12c1, and 12d1, respectively. The conductive layer 133 is also connected to the post electrodes 45s, 46s, 47s, and 48s connected to the source electrodes of the semiconductor chips 12a2, 12b2, 12c2, and 12d2, respectively.

Conductive layers 136a, 136b, 136c, and 136d are connected to the post electrodes 41g, 42g, 43g, and 44g connected to the gate electrodes of the semiconductor chips 12a1, 12b1, 12c1, and 12d1, respectively. Conductive layers 137a, 137b, 137c, and 137d are connected to the post electrodes 45g, 46g, 47g, and 48g connected to the gate electrodes of the semiconductor chips 12a2, 12b2, 12c2, and 12d2, respectively. In addition, the conductive member 51 is connected to the conductive layer 133 at a position pt1, and the conductive member 52 is connected to the conductive layer 133 at a position pt2.

Note that the inner conductive layer L3 is provided with a lower-arm-side auxiliary source terminal connection portion 2s-3, which is connected to the auxiliary source terminal connection portion 2s-4 depicted in FIG. 4. The inner conductive layer L3 is also provided with a lower-arm-side gate terminal connection portion 2g-3, which is connected to the gate terminal connection portion 2g-4 depicted in FIG. 4.

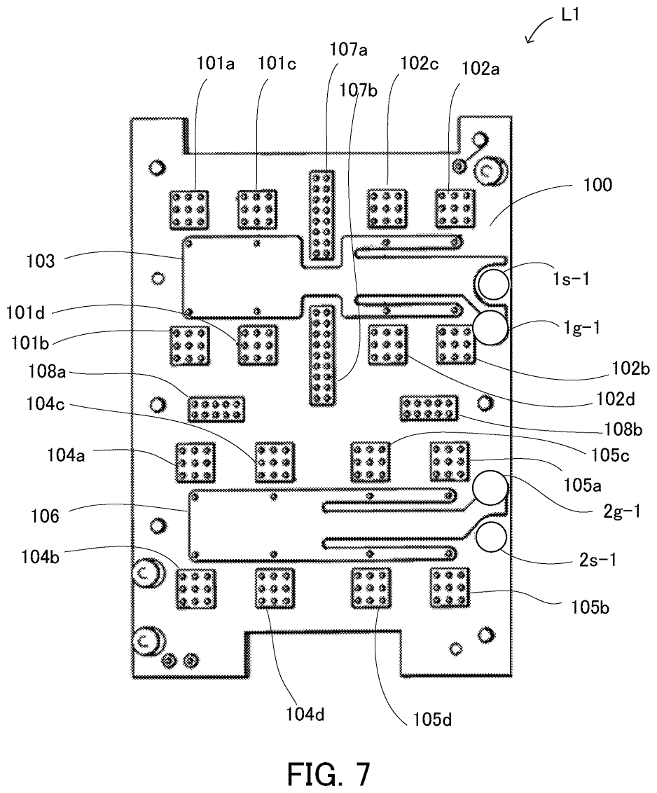

The inner conductive layer L2 depicted in FIG. 6 is located between the inner conductive layer L3 and an uppermost wiring portion L1 depicted in FIG. 7. On the upper arm side of the inner conductive layer L2, a conductive layer 121 (first conductive layer) is connected to the post electrodes 31s, 32s, 33s, and 34s connected to the source electrodes of the semiconductor chips 11a1, 11b1, 11c1, and 11d1, respectively. Conductive layers 124a, 124b, 124c, and 124d are connected to the post electrodes 31g, 32g, 33g, and 34g connected to the gate electrodes of the semiconductor chips 11a1, 11b1, 11c1, and 11d1, respectively. In addition, the intermediate conductive member 61 is connected to the conductive layer 121 at the position pt3.

A conductive layer 122 (first conductive layer) is connected to the post electrodes 35s, 36s, 37s, and 38s connected to the source electrodes of the semiconductor chips 11a2, 11b2, 11c2, and 11d2, respectively. Conductive layers 125a, 125b, 125c, and 125d are connected to the post electrodes 35g, 36g, 37g, and 38g connected to the gate electrodes of the semiconductor chips 11a2, 11b2, 11c2, and 11d2, respectively. In addition, the intermediate conductive member 62 is connected to the conductive layer 122 at the position pt4.

Note that the inner conductive layer L2 is provided with an upper-arm-side auxiliary source terminal connection portion 1s-2, which is connected to the auxiliary source terminal connection portion 1s-3 depicted in FIG. 5. The inner conductive layer L2 is also provided with the upper-arm-side gate terminal connection portion 1g-2, which is connected to the gate terminal connection portion 1g-3 depicted in FIG. 5.

On the lower arm side of the inner conductive layer L2, a conductive layer 123 (second conductive layer) is connected to the post electrodes 41s, 42s, 43s, and 44s connected to the source electrodes of the semiconductor chips 12a1, 12b1, 12c1, and 12d1, respectively. The conductive layer 123 is also connected to the post electrodes 45s, 46s, 47s, and 48s connected to the source electrodes of the semiconductor chips 12a2, 12b2, 12c2, and 12d2, respectively.

Conductive layers 126a, 126b, 126c, and 126d are connected to the post electrodes 41g, 42g, 43g, and 44g connected to the gate electrodes of the semiconductor chips 12a1, 12b1, 12c1, and 12d1, respectively. Conductive layers 127a, 127b, 127c, and 127d are connected to the post electrodes 45g, 46g, 47g, and 48g connected to the gate electrodes of the semiconductor chips 12a2, 12b2, 12c2, and 12d2, respectively. In addition, the conductive member 51 is connected to the conductive layer 123 at the position pt1, and the conductive member 52 is connected to the conductive layer 123 at the position pt2.

The inner conductive layer L2 is provided with a lower-arm-side auxiliary source terminal connection portion 2s-2, which is connected to the auxiliary source terminal connection portion 2s-3 depicted in FIG. 5. The inner conductive layer L2 is also provided with a lower-arm-side gate terminal connection portion 2g-2, which is connected to the gate terminal connection portion 2g-3 depicted in FIG. 5.

FIG. 7 depicts an example pattern configuration of the uppermost wiring portion. The uppermost wiring portion L1 is positioned on the uppermost layer of the printed circuit board 18. On the uppermost wiring portion L1, a conductive layer is provided on an insulating layer 100.

On the upper arm side of the uppermost wiring portion L1, conductive layers 101a, 101b, 101c, and 101d are connected to the post electrodes 31s, 32s, 33s, and 34s connected to the source electrodes of the semiconductor chips 11a1, 11b1, 11c1, and 11d1, respectively. Conductive layers 102a, 102b, 102c, and 102d are connected to the post electrodes 35s, 36s, 37s, and 38s connected to the source electrodes of the semiconductor chips 11a2, 11b2, 11c2, and 11d2, respectively.

A conductive layer 103 is connected to the post electrodes 31g, 32g, 33g, and 34g connected to the gate electrodes of the semiconductor chips 11a1, 11b1, 11c1, and 11d1, respectively. The conductive layer 103 is also connected to the post electrodes 35g, 36g, 37g, and 38g connected to the gate electrodes of the semiconductor chips 11a2, 11b2, 11c2, and 11d2, respectively.

Note that the uppermost-layer wiring portion L1 is provided with an upper-arm-side auxiliary source terminal connection portion 1s-1, which is connected to the auxiliary source terminal connection portion 1s-2 depicted in FIG. 6. An auxiliary source terminal (corresponding to the auxiliary source terminal S1 depicted in FIG. 3) is also connected as an external terminal to the auxiliary source terminal connection portion 1s-1.

The uppermost wiring portion L1 is also provided with an upper-arm-side gate terminal connection portion 1g-1, and this gate terminal connection portion 1g-1 is connected to the gate terminal connection portion 1g-2 depicted in FIG. 6 and the conductive layer 103. A gate terminal (corresponding to the gate terminal G1 depicted in FIG. 3) is also connected as an external terminal to the gate terminal connection portion 1g-1.

On the lower arm side of the uppermost wiring portion L1, conductive layers 104a, 104b, 104c, and 104d are connected to the post electrodes 41s, 42s, 43s, and 44s connected to the source electrodes of the semiconductor chips 12a1, 12b1, 12c1, and 12d1, respectively. Conductive layers 105a, 105b, 105c, and 105d are connected to the post electrodes 45s, 46s, 47s, and 48s connected to the source electrodes of the semiconductor chips 12a2, 12b2, 12c2, and 12d2, respectively.

A conductive layer 106 is connected to the post electrodes 41g, 42g, 43g, and 44g connected to the gate electrodes of the semiconductor chips 12a1, 12b1, 12c1, and 12d1, respectively. The conductive layer 106 is also connected to the post electrodes 45g, 46g, 47g, and 48g connected to the gate electrodes of the semiconductor chips 12a2, 12b2, 12c2, and 12d2, respectively.

Note that the uppermost wiring portion L1 is provided with a lower-arm-side auxiliary source terminal connection portion 2s-1, which is connected to the auxiliary source terminal connection portion 2s-2 depicted in FIG. 6. An auxiliary source terminal (corresponding to the auxiliary source terminal S2 depicted in FIG. 3) is also connected as an external terminal to the auxiliary source terminal connection portion 2s-1.

The uppermost wiring portion L1 is also provided with a lower-arm-side gate terminal connection portion 2g-1, and the gate terminal connection portion 2g-1 is connected to the gate terminal connection portion 2g-2 and the conductive layer 106 depicted in FIG. 6. A gate terminal (corresponding to the gate terminal G2 depicted in FIG. 3) is also connected as an external terminal to the gate terminal connection portion 2g-1.

On the other hand, a conductive layer 107a is connected to the conductive member 51, and a conductive layer 107b is connected to the conductive member 52. A conductive layer 108a is connected to the intermediate conductive member 61, and a conductive layer 108b is connected to the intermediate conductive member 62.

It is possible to use insulating resin for the insulating layer 100 of the printed circuit board 18. As examples of insulating resin, phenol resin, epoxy resin, polyimide resin, or glass epoxy resin is used. The conductive layers of the uppermost wiring portion L1, the inner conductive layers L2 and L3, and the lowermost conductive layer L4 of the printed circuit board 18 are made of a metal with superior electrical conductivity.

Example metals include copper, aluminum, or an alloy containing at least one of these metals. The surface of the conductive layer may be plated to improve corrosion resistance. Examples of the plating material used here include aluminum, nickel, titanium, chromium, molybdenum, tantalum, niobium, tungsten, vanadium, bismuth, zirconium, hafnium, gold, silver, platinum, palladium, or an alloy containing at least one of these metals.

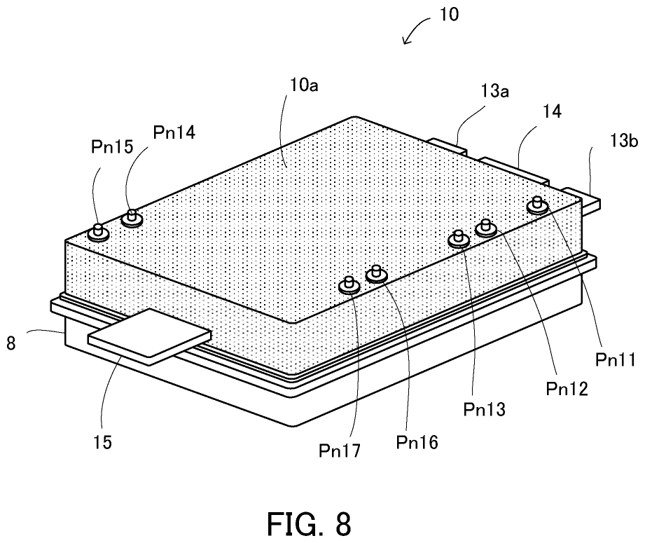

FIG. 8 depicts an example overview of a semiconductor device. The insulating circuit board 17 and the printed circuit board 18 mounted on the cooler 8 are fixed by fitting attachment pins Pn11, Pn12, Pn13, Pn14, Pn15, Pn16, and Pn17 into the holes h1, h2, h3, h4, h5, h6, and h7 respectively, depicted in FIG. 1. The insulating circuit board 17 and the printed circuit board 18 are encapsulated by the insulating encapsulating member 10a.

The insulating encapsulating member 10a may be a thermosetting resin. Examples of the thermosetting resin include epoxy resin, phenol resin, maleimide resin, and polyester resin. Here, epoxy resin is preferable. The insulating encapsulating member 10a may also be an underfill material. As one example, the underfill material contains, an epoxy-based resin as a main component, has a curing temperature of about 180 °C, and contains a filler material made of an inorganic material. As one example, an inorganic material with high thermal conductivity, such as boron nitride, aluminum nitride, or silicon nitride is used as the filler material.

Here, the flow of signals through the printed circuit board 18 when the semiconductor chips 11 and 12 are powered will be described. The conductive layers 131 and 132 (first conductive layers) of the inner conductive layer L3 and the conductive layers 121 and 122 (first conductive layers) of the inner conductive layer L2 of the printed circuit board 18 are conductively connected to the source electrodes of the semiconductor chips 11 of the upper arm portion A.

The conductive layer 131 of the inner conductive layer L3 and the conductive layer 121 of the inner conductive layer L2 are conductively connected to the intermediate conductive member 61 connected to the conductive plate 17e (second conductive plate) of the insulating circuit board 17, and the conductive layer 132 of the inner conductive layer L3 and the conductive layer 122 of the inner conductive layer L2 are conductively connected to the intermediate conductive member 62 connected to the conductive plate 17e of the insulating circuit board 17.

Accordingly, when the semiconductor chips 11 are turned on, a signal outputted from the source electrodes through the drain electrode of the semiconductor chips 11 flow toward the conductive layers 131, 132, 121, and 122 of the printed circuit board 18, and the signal that has flowed through the conductive layers 131, 132, 121, and 122 flows toward the conductive plate 17e through the intermediate conductive members 61 and 62 of the insulating circuit board 17 (the source electrodes of the semiconductor chips 11→the first conductive layer→the second conductive plate via the intermediate conductive member).

The conductive plate 17e on which the intermediate conductive members 61 and 62 are disposed is connected to the drain electrodes of the semiconductor chips 12 in the lower arm portion B. In addition, the conductive layer 133 (second conductive layer) of the inner conductive layer L3 and the conductive layer 123 (second conductive layer) of the inner conductive layer L2 of the printed circuit board 18 are conductively connected to the source electrodes of the semiconductor chips 12.

Accordingly, the signal flowing from the printed circuit board 18 to the conductive plate 17e through the intermediate conductive members 61 and 62 is inputted into the drain electrodes of the semiconductor chips 12. When the semiconductor chips 12 are turned on, the signal is outputted from the source electrodes through the drain electrodes of the semiconductor chips 12, and the signal flows toward the conductive layers 133 and 123 of the printed circuit board 18 (second conductive plate→drain electrodes of semiconductor chips 12→source electrodes →second conductive layer).

The conductive layers 133 and 123 of the printed circuit board 18 are conductively connected to the conductive members 51 and 52 connected to the conductive plate 17c (the third conductive plate) of the insulating circuit board 17, and the external terminal 14 (N terminal) is connected to the conductive plate 17c. Accordingly, the signal flowing through the conductive layers 133 and 123 of the printed circuit board 18 flows toward the conductive members 51 and 52 of the insulating circuit board 17, and the signal that has flowed through the conductive members 51 and 52 flows to the external terminal 14 (second conductive layer→third conductive plate via conductive member→external terminal (N terminal)).

As described above, the semiconductor device 10 is configured so that the conductive plate 17c that extends from the center of the insulating circuit board 17 toward the outer edge and the conductive layers 133 and 123 of the printed circuit board 18 are connected by the conductive members 51 and 52, so that a signal flowing on the printed circuit board 18 is caused to flow to the conductive plate 17c side of the insulating circuit board 17, thereby achieving a heat dissipation path for the printed circuit board 18. By doing so, it is possible to suppress generation of Joule heat at the printed circuit board 18 when the semiconductor chips 11 and 12 are powered, and it is possible to improve the heat dissipation performance of the printed circuit board 18.

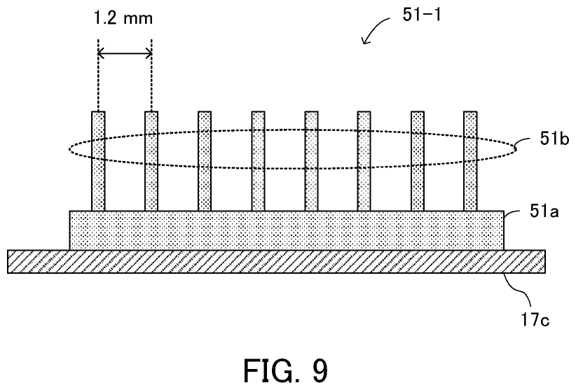

Next, the shapes of the conductive members 51 and 52 will be described with reference to FIGS. 9 to 11. Since the conductive members 51 and 52 use the same component, the conductive member 51 will be described.

FIG. 9 depicts a first example configuration of a conductive member. The conductive member 51-1 of the first configuration example includes a conductive base portion 51a and a plurality of conductive pins 51b. The lower surface of the conductive base portion 51a is connected to the conductive plate 17c, and the conductive pins 51b are connected to the upper surface of the conductive base portion 51a.

The conductive pins 51b are inserted into the printed circuit board 18 and, for the inner conductive layers L3 and L2, are connected to the conductive layer 133 of the inner conductive layer L3 and the conductive layer 123 of the inner conductive layer L2. The center-to-center distance of the conductive pins 51b is 1.2 mm or longer, for example. Any freely chosen number of conductive pins 51b may be provided in keeping with the design.

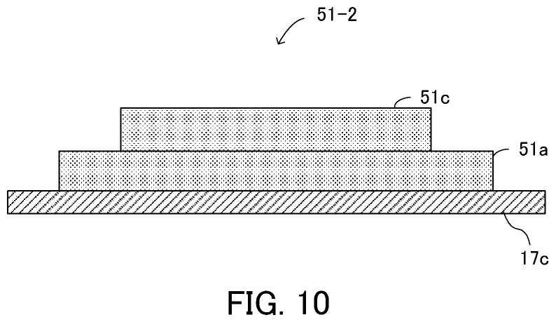

FIG. 10 depicts a second example configuration of a conductive member. The conductive member 51-2 of this second example configuration includes a conductive base portion 51a and a single conductive block 51c. The lower surface of the conductive base portion 51a is connected to the conductive plate 17c and the conductive block 51c is connected to the upper surface of the conductive base portion 51a. The conductive block 51c is inserted into the printed circuit board 18 and, for the inner conductive layers L3 and L2, is connected to the conductive layer 133 of the inner conductive layer L3 and the conductive layer 123 of the inner conductive layer L2.

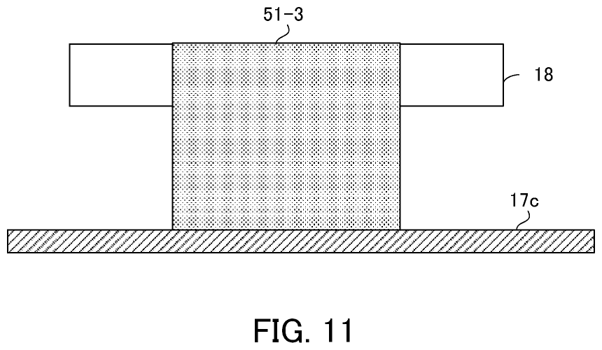

FIG. 11 is a diagram illustrating a third example configuration of a conductive member. The conductive member of the third example configuration is a conductive inlay 51-3. The conductive inlay 51-3 is embedded in the printed circuit board 18 and, for the inner conductive layers L3 and L2, is connected to the conductive layer 133 of the inner conductive layer L3 and the conductive layer 123 of the inner conductive layer L2. The lower surface of the conductive inlay 51-3 is connected to the conductive plate 17c.

The conductive members 51 and 52 and the intermediate conductive members 61 and 62 are made of a metal with superior electrical conductivity and heat dissipation. Example metals include copper, aluminum, or an alloy containing at least one of these metals. To improve corrosion resistance of the conductive plates 17b, 17c, 17d, and 17e, a plating treatment may be performed. Examples of the plating material used here include nickel, nickel-phosphorus alloy, and nickel-boron alloy.

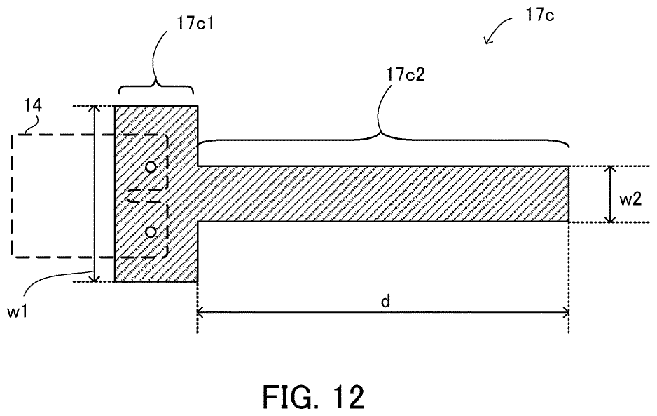

Next, the shape of the conductive plate 17c (third conductive plate) will be described with reference to FIG. 12. FIG. 12 depicts an example shape of a conductive plate. The conductive plate 17c includes a first conductive pattern member 17c1, which has a first width w1 and to which the external terminal 14 is connected, and a second conductive pattern member 17c2, which has a second width w2 that is smaller than the first width w1 and extends from the center of the insulating circuit board 17 toward the outer edge by a predetermined length d. The second width w2 may be 2 mm or more and 10 mm or less. The predetermined length d may be 5 mm or more and 60 mm or less. As examples, the second width w2 may be 4 mm and the predetermined length d may be 28 mm.

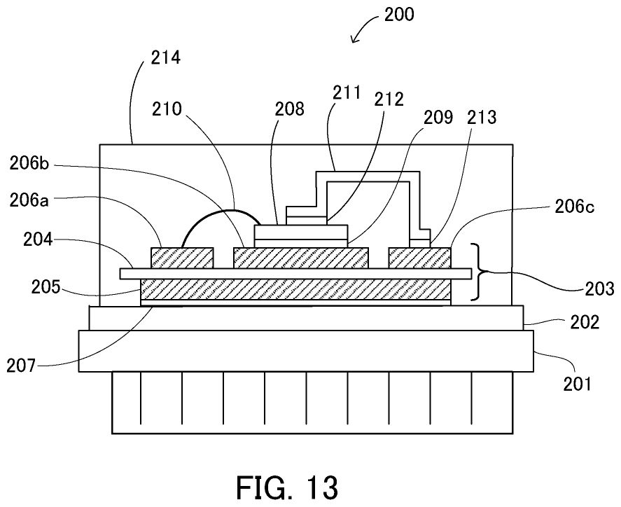

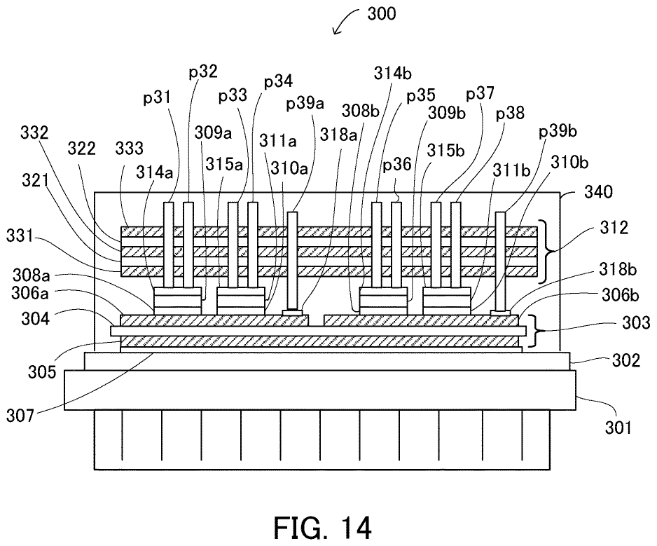

Next, a semiconductor device according to a comparative example will be described with reference to FIGS. 13 and 14. FIG. 13 depicts an example cross section of a semiconductor device according to a first comparative example. A semiconductor device 200 according to the first comparative example includes a semiconductor chip and an insulating circuit board, and has a wiring structure that using wires and lead frames.

In the semiconductor device 200, one surface of a heat dissipation plate 202 is mounted on the upper surface of a cooler 201 so as to face the cooler 201, and an insulating circuit board 203 is mounted on the other surface of the heat dissipation plate 202. The insulating circuit board 203 includes an insulating member 204, a metal plate 205, and conductive plates 206a, 206b, and 206c. The metal plate 205 of the insulating circuit board 203 is connected via a bonding material 207 to the heat dissipation plate 202. A semiconductor chip 208 is connected via a bonding material 209 onto the conductive plate 206b of the insulating circuit board 203.

On the other hand, a wire 210 is a bonding wire made of aluminum, and connects an upper surface electrode of the semiconductor chip 208 and the conductive plate 206a. One end of a lead frame 211 is connected via a bonding material 212 to an upper surface electrode of the semiconductor chip 208, and the other end of the lead frame 211 is connected via a bonding material 213 to the conductive plate 206c. The insulating circuit board 203 on which the semiconductor chip 208 has been mounted is encapsulated by an insulating encapsulating member 214.

FIG. 14 is an example cross section of a semiconductor device according to a second comparative example. A semiconductor device 300 according to the second comparative example includes a semiconductor chip and an insulating circuit board, and has a wiring structure using a printed circuit board and pin terminals.

A heat dissipation plate 302 is mounted on the upper surface of a cooler 301 so that one surface of the heat dissipation plate 302 faces the upper surface of the cooler 301, and an insulating circuit board 303 is mounted on the other surface of the heat dissipation plate 302. The insulating circuit board 303 includes an insulating member 304, a metal plate 305, and conductive plates 306a and 306b. The metal plate 305 of the insulating circuit board 303 is connected via a bonding material 307 to the heat dissipation plate 302.

On the conductive plate 306a of the insulating circuit board 303, a semiconductor chip 309a is connected via a bonding material 308a, and a semiconductor chip 311a is further connected via a bonding material 310a. On the conductive plate 306b of the insulating circuit board 303, a semiconductor chip 309b is connected via a bonding material 308b, and a semiconductor chip 311b is further connected via a bonding material 310b.

A printed circuit board 312 has a multilayer structure in which insulating layers 321 and 322 and conductive layers 331, 332, and 333 are stacked on each other, and is disposed facing the insulating circuit board 303. One end of each conductive pin terminal p31 and p32 is connected via the bonding material 314a to an upper surface electrode of the semiconductor chip 309a, and the other ends pass through the printed circuit board 312 and are connected to the conductive layers 331, 332, and 333. One end of each conductive pin terminal p33 and p34 is connected via the bonding material 315a to an upper surface electrode of the semiconductor chip 311a, and the other ends pass through the printed circuit board 312 and are connected to the conductive layers 331, 332, and 333.

One end of each conductive pin terminal p35 and p36 is connected via the bonding material 314b to an upper surface electrode of the semiconductor chip 309b, and the other ends pass through the printed circuit board 312 and are connected to the conductive layers 331, 332, and 333. One end of each conductive pin terminal p37 and p38 is connected via the bonding material 315b to an upper surface electrode of the semiconductor chip 311b, and the other ends pass through the printed circuit board 312 and are connected to the conductive layers 331, 332, and 333.

One end of a conductive pin terminal p39a is connected via a bonding material 318a to the conductive plate 306a, and the other end passes through and protrudes from the printed circuit board 312. One end of a conductive pin terminal p39b is connected via a bonding material 318b to the conductive plate 306b, and the other end passes through and protrudes from the printed circuit board 312. The insulating circuit board 303 on which the semiconductor chips 309a, 311a, 309b, and 311b are mounted and the printed circuit board 312 are encapsulated by an insulating encapsulating member 340.

In the semiconductor device 300, the printed circuit board 312 is supported by connecting the conductive pin terminals p31, p32, p33, p34, p35, p36, p37, p38, p39a, and p39b to the printed circuit board 312 and the insulating circuit board 303, with two circuit unit assemblies electrically connected via the printed circuit board 312.

Here, in the semiconductor device 200 according to the first comparative example, a wire and a lead frame are used as the wiring structure. When a wiring structure includes wires and lead frames in this way, a plurality of connection areas, such as bonding areas, need to be provided on the insulating circuit board 203 to form circuits, leading to the problem that it is difficult to reduce the size of the device.

On the other hand, in the semiconductor device 300 according to the second comparative example, a printed circuit board and pin terminals are provided as the wiring structure. This means that unlike a wiring structure using wires and lead frames, there is no need to provide a plurality of connection areas on the insulating circuit board, so that high-density mounting is possible and device miniaturization is possible.

However, since the printed circuit board 312 disposed above the semiconductor chips is constructed with the wiring of the individual semiconductor chips grouped together, there is a problem in that generation of Joule heat increases when the semiconductor chips are powered, which increases the amount of heat generated by the printed circuit board 312 and causes deterioration in heat dissipation performance.

On the other hand, in the semiconductor device 10 of the present embodiment, a heat dissipation pattern member (the conductive plate 17c) is provided on the insulating circuit board 17, and the heat dissipation pattern member of the insulating circuit board 17 and the conductive layer of the printed circuit board 18 disposed facing the insulating circuit board 17 are connected by the conductive members 51 and 52, so that the Joule heat generated at the printed circuit board 18 is dissipated via the conductive members 51 and 52 toward the insulating circuit board 17. By doing so, it is possible to further improve the heat dissipation performance of the printed circuit board 18 while achieving miniaturization of the device.

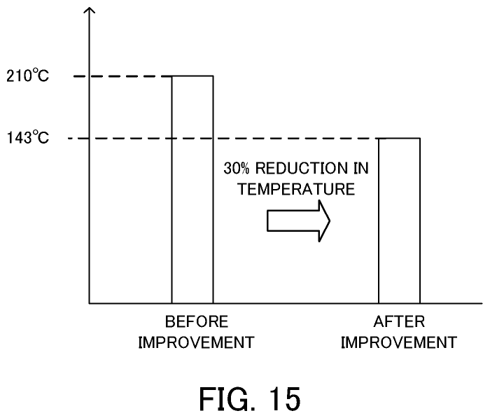

FIG. 15 depicts an analysis result of Joule heat of a printed circuit board. The maximum temperature of a central part of the printed circuit board of a semiconductor device before improvement (as one example, the semiconductor device 300 according to the second comparative example) reaches 210 °C when the semiconductor chips are powered. On the other hand, the maximum temperature of a central part of the printed circuit board 18 of the improved semiconductor device 10 is reduced to 143 °C, realizing a 30% reduction in temperature.

Although the embodiment has been illustrated above, the configuration of each unit described in the embodiment may be replaced with other configurations with the same function. In addition, any other components or processes may be added. Furthermore, any two or more configurations (features) of the above-described embodiment may be combined.

According to one aspect, it is possible to improve the heat dissipation performance of a printed circuit board.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that various changes, substitutions, and alterations could be made hereto without departing from the spirit and scope of the invention.

What is claimed is:

1. A semiconductor device, comprising:
an insulating circuit board including a first conductive plate, a second conductive plate, and a third conductive plate disposed on an insulating member, the third conductive plate extending from a center of the insulating circuit board toward an outer edge of the insulating circuit board;
a first semiconductor chip disposed on the first conductive plate;
a first external terminal connected to the first conductive plate;
a second semiconductor chip disposed on the second conductive plate, each of the first and second semiconductor chips having an electrode on an upper surface thereof;
a second external terminal connected to the second conductive plate;
a third external terminal connected to the third conductive plate;
a printed circuit board, including:
a first conductive layer, which is conductively connected to the electrode of the first semiconductor chip and the second conductive plate,
a second conductive layer, which is conductively connected to the electrode of the second semiconductor chip and the third conductive plate, the second conductive layer being disposed facing the third conductive plate, and
an insulating layer which is disposed between the first conductive layer and the second conductive layer,
the printed circuit board being disposed facing the insulating circuit board with the first semiconductor chip and the second semiconductor chip in between; and
a conductive member that connects the third conductive plate and the second conductive layer, wherein
the insulating member is configured to have a cooler provided on a lower surface thereof.

2. The semiconductor device according to claim 1, wherein the third conductive plate includes
a first conductive pattern member, which has a first width and is connected to the third external terminal, and
a second conductive pattern member, which has a second width smaller than the first width, and extends from the center of the insulating circuit board toward the outer edge of the insulating circuit board by a predetermined length.

3. The semiconductor device according to claim 2, wherein the second width is 2 mm or more and 10 mm or less, and the predetermined length is 5 mm or more and 60 mm or less.

4. The semiconductor device according to claim 1, wherein the conductive member includes a plurality of conductive pins that connect the third conductive plate and the second conductive layer.

5. The semiconductor device according to claim 4, wherein a center-to-center distance between the conductive pins is 1.2 mm or more.

6. The semiconductor device according to claim 1, wherein the conductive member includes a single conductive block that connects the third conductive plate and the second conductive layer.

7. The semiconductor device according to claim 1, wherein the conductive member is a conductive inlay embedded in the printed circuit board.

8. The semiconductor device according to claim 1, further comprising an intermediate conductive member that is connected to the second conductive plate and is positioned in an intermediate portion of the insulating circuit board,
wherein the first conductive layer is conductively connected via the intermediate conductive member to the electrode of the first semiconductor chip and the second conductive plate.
